(19) United States
(12) Patent Application Publication
(10) Pub. No.: US 2020/0266879 A1
(43) Pub. Date: Aug. 20, 2020

(54) Repeater for Relaying Telecommunications Signals

(71) Applicant: KATHREIN SE, Rosenheim (DE)

(72) Inventors: Michael Yan Wah Chia, Singapore (SG); Wolfgang Mummert, Rosenheim (DE)

(21) Appl. No.: 16/649,307

(22) PCT Filed: Sep. 22, 2017
(86) PCT No.: PCT/IB2017/055762

§ 371 Date: Mar. 20, 2020

(51) Int. Cl. H04B 7/155; H04B 7/08; H04B 7/06; H03F 3/24

(52) U.S. Cl. CPC H04B 7/15535; H04B 7/0828; H03F 2200/102; H03F 3/24; H04B 7/0617

(57) ABSTRACT

A repeater (10) for relaying telecommunication signals (20) between a base station (30) and a plurality of mobile users (40) is disclosed. The repeater (10) comprises a down converter (110) for converting the telecommunications signals (20) to an intermediate frequency (IF) from a transmission frequency and an up converter (150) for converting the telecommunication signals (20) from an intermediate frequency to the transmission frequency. An IF beamforming processor network (210) arranged between the downconverter (111) and the up converter (150). The IF beamforming processor network (210) comprises a first phase shifter network (310; 320) for phase shifting down converted telecommunications signals (202; 222), a second phase shifter network (320) for phase shifting telecommunications signals on the downlink; and a coupler (230) arranged between the first phase shifter network (310) and the second phase shifter network (320; 310), the coupler (330) being adapted for coupling a portion of the phase shifted down converted telecommunications signals and providing control signals to the first phase shifter network (310) based on signal power.

### CROSS REFERENCE TO RELATED APPLICATIONS

The present application is a U.S. National Stage of International Application No. PCT/IB2017/055762 filed on Sep. 22, 2017. The aforementioned international application is hereby incorporated by reference in its entirety.

### BACKGROUND OF THE INVENTION

### Field of the Invention

The invention relates to a repeater for relaying telecommunications signals between a base station and a plurality of mobile users, as well as a method therefor.

### Brief Description of the Related Art

It is well-known that there is an increasing demand for mobile telecommunications services and thus also for mobile telecommunications equipment. Mobile telecommunications services use several standards. The most commonly used standards employed are the UMTS (3G) standard, which has been in use for many years, and the LTE (4G) standard which has been introduced in the past few years. The next generation of standards for mobile telecommunications networks or wireless systems is designated 5G and aims at achieving a higher capacity and faster data transfer than the current 4G standards. This next generation standard will enable a higher density of mobile broadband users and support device-to-device communications.

The next generation mobile networks alliance has defined the requirements that the 5G standard should fulfil. These requirements include data rates of tens of megabits per second for tens of thousands of users, data rates of hundred megabits per second Metropolitan areas, as well as rates of several gigabits per second in an office floor.

Research is currently being carried out into wireless millimetre wave data communication in microcells for use in offices and in macrocells for use outdoors. It has been established that the communication is often limited by a line of sight (LOS) propagation channel due to high gain antennas. The blockage of the line of sight between a base station and the mobile using mobile stations leads to the millimetre wave signals being obstructed. This problem is worsened by mobility of the mobile users when the mobile users are driving or walking. The telecommunications beam needs to be steered to optimise reception of the telecommunications beam by the mobile users. There is therefore a need to use beamforming and beamsteering solutions to improve the reception of the telecommunications signals for these users.

Repeaters have been developed to improve the reception of telecommunications signals. Currently, the beamforming and the beam steering solutions for the repeaters are expensive, complex, and unwieldy in a commercial millimetre wave environment. There is therefore a need to reduce the costs and make such repeaters less costly.

It is known in the art that beamforming or beamsteering techniques can be implemented in either the analog domain or the digital domain. For example, U.S. Pat. No. 6,411,256 (Lier et al, assigned to Lockheed Martin Corporation) teaches beamforming techniques in the analog domain and European Patent No. EP 2 584 651 (IMEC) shows hybrid beam forming techniques.

The U.S. Published Patent Application No. 2002/098872 A1 (Judson, assigned to Qualcomm) teaches a method and system for forward link beamforming in wireless communications. An antenna beam pattern is formed using adaptive antenna array technology on the forward link of a wireless communication system. A control signal can be sent by a mobile user on a return link to control the antenna beam pattern. The control signal can include information about the power received by the mobile user.

US Published Patent Application No. 2003/0043071 A1 (Lily et al) teaches an electro-mechanical scanned array system. The antenna system includes a beamformer to steer a beam of the antenna system, which is constant over a broad band of frequencies.

U.S. Pat. No. 6,850,130 B1 (Göttl et al, assigned to Kathrein) teaches a high frequency phase shifter for direct RF beamforming. The phase shifter has a pivotable tapping element.

None of the beamforming systems known in the art are suitable for use in a repeater for the millimetre wave telecommunications system.

Repeaters for wireless communications are for example known, for example from U.S. Pat. No. 7,577,398 B2 (Judd et al, assigned to Andrew LLC). This patent teaches a repeater having a housing with a pair of oppositely facing surfaces. At least one antenna element is mounted on each of the surfaces and the antenna element radiates energy in a direction opposite to that of an antenna element mounted on the other of the surface. An electronic circuit within the housing operatively couples signals between one antenna element and another antenna element.

None of the beamforming systems known in the art are suitable for use in a repeater for the millimetre wave telecommunications system.

### SUMMARY OF THE INVENTION

The present application discloses a repeater for relaying telecommunication signals between a base station and a plurality of mobile users. The repeater comprises a down converter for converting the telecommunications signals to down converted telecommunications signals at an intermediate frequency (IF) from a transmission frequency and an up converter for converting the down converted telecommunication signals from the intermediate frequency to the transmission frequency. An IF beamforming processor network is arranged between the down converter and the up converter and comprises both a first phase shifter network for phase shifting the down converted telecommunications signals to form the phase shifted down converted telecommunications signals as well as a second phase shifter network for further phase shifting the phase shifted down converted telecommunications signals. A first coupler is arranged between the first phase shifter network and the second phase shifter network. This first coupler is adapted for coupling a portion of the phase shifted down converted telecommunications signals and providing control signals to the first phase shifter network based on the coupled portion.

In this configuration, the first coupler measures the power in the telecommunications signals and thus provides the control signals to adapt the weighting coefficients in the IF beamforming processor network to change the phase and amplitude of the components of the telecommunications signals.

The repeater has a first power detector connected to the first coupler for detecting the power of the phase shifted down converted telecommunication signals. The values of measure in the power detector is then used to generate the control signals and thus maximise the amount of power received in the telecommunications signals. The use of power measurement simplifies the system and enables cheaper components to be used.

In one aspect of the invention, the repeater comprises an external antenna for sending data about the phase shifted down converted telecommunications signals to an external network controller. In another aspect, the data is sent through a connector to a public computer network, such as an Internet connection.

The repeater can further comprise a second power detector for passing values of the power from the combiner to the processor and thus adapt the telecommunications signals on the bidirectional link from the repeater to the mobile stations.

This document also discloses a method for relaying telecommunications signals comprising down converting the telecommunication signals from a radio frequency to an intermediate frequency, phase shifting the down converted telecommunications signals, measuring power of the phase shifted down converted telecommunications signals, adjusting weighting coefficients dependent on the measured power: up converting the phase shifted down converted telecommunications signals, and relaying the up converted telecommunications signals.

The method of measuring of the power of the down converted telecommunication signals comprises in one aspect measuring envelope of the beam formed telecommunications signals.

The weighting coefficients can be either calculated in a network controller or by using a look-up table.

### BRIEF DESCRIPTION OF THE DRAWINGS

For a more complete understanding of the present invention and the advantages thereof, reference is now made to the following description and the accompanying drawings, in which:

FIG. 1 shows an example of a location in which a repeater is used.

FIG. 2 shows an example of the repeater with an IF beam forming processor network.

FIG. 3 shows a first example of the IF beam forming processor network.

FIG. 4 shows a second example of the IF beam forming processor network.

FIG. 5 shows a third example of the IF beam forming processor network.

FIG. 6 shows a fourth example of the IF beam forming processor network.

FIG. 7 shows an example of a phase shifter network with a combiner with RET/RCU

FIG. 8 shows an example of a phase shifter network with a divider with RET/RCU

FIG. 9 shows an example of a rotary phase shifter.

FIG. 10A shows an example of a planar phase shifter

FIG. 10B shows an example of a trombone phase shifter

FIG. 10C shows an example of a remote control unit with a shaft

FIG. 10D shows an example of a remote control unit with multiple shafts converting to a rotary motion.

FIG. 11 shows a flow chart of a method of operation.

FIG. 12 shows a flow chart of a second method of operation.

### DETAILED DESCRIPTION OF THE INVENTION

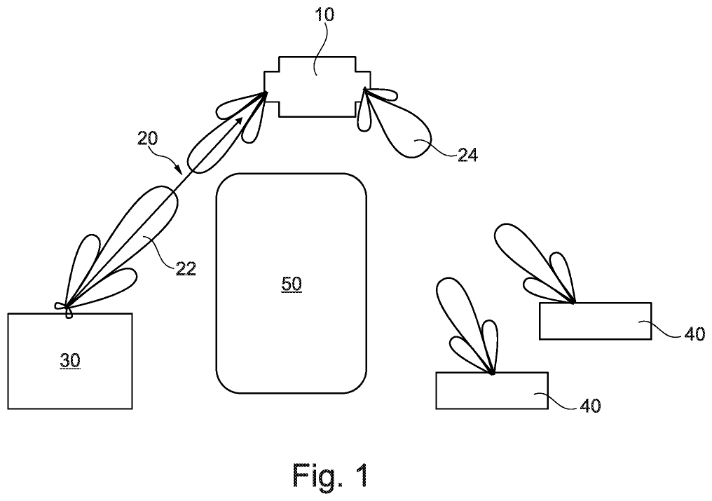

FIG. 1 shows an example of a location in which a repeater 10 is used to relay telecommunication signals 20 from a base station 30 to a plurality of mobile stations 40 in use by mobile users. It will be appreciated that some of the mobile stations 40 may in fact be stationary or fixed. The repeater 10 shown in FIG. 1 and described in this document is particularly suitable when there is no direct line of sight between the base station 30 and the plurality of mobile stations 40. This lack of line of sight is represented in FIG. 1 as an obstruction 50. The obstruction 50 could, for example, be a building, a screen, or a wall. The telecommunications signals 22 on the downlink and uplink modes on the bidirectional link to the base station 30 and a mobile signal beam 24 on the uplink and downlink modes on the bidirectional link to the mobile stations 40 are assumed to be in the 28 GHz band, but this is not limiting of the invention.

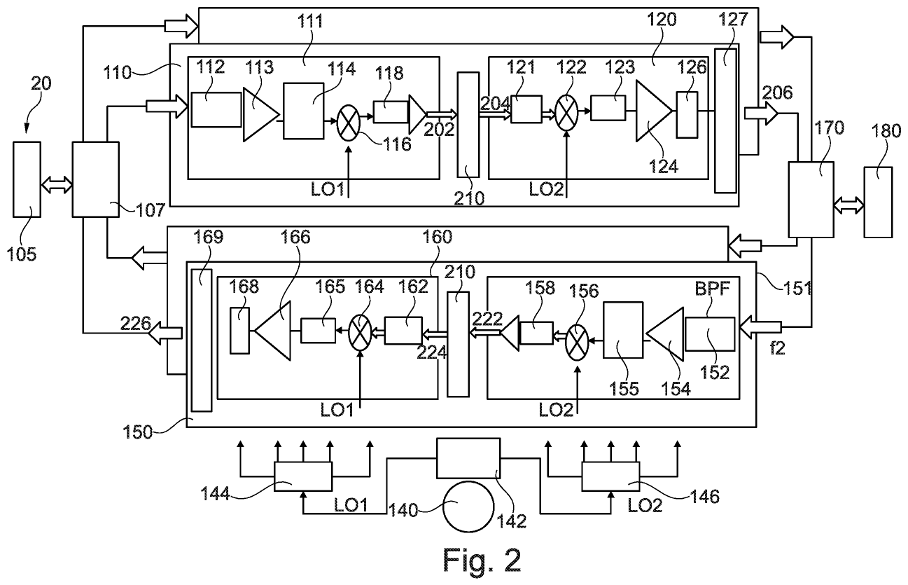

An example of the repeater 10 that can be used in the system of FIG. 1 is shown in FIG. 2. It will be seen that the repeater 10 comprises a donor antenna 105 for transceiving the one or more telecommunication signals 20 on the bidirectional link from the base station 30. The telecommunication signals 20 are passed between the donor antenna 105 and a first duplexer network 107. The first duplexer network 107 is connected to a transmission network 110 and to a receiver network 150. The function of the first duplexer network 107 is to pass the telecommunications signals received from the donor antenna 105 to the transmission network 110 and to pass the telecommunications signals received from the receiver network 150 to the donor antenna 105.

The transmission network 110 comprises a down converter 111 in which the incoming telecommunications signals 20 from the base station uplink received at the donor antenna 105 are down converted from their transmission frequency to an intermediate frequency (IF) and the down converted telecommunication signals 202 are passed to an IF beamforming processor network 210. The function of the IF beamforming processor network 210 will be described later.

After beamforming has been carried out in the IF beamforming processor network 210 the phase shifted down converted telecommunications signals 204 are passed to an up converter 120 at which they are converted from the intermediate frequency to the transmission frequency. The up converted telecommunications signals 206 are passed through a second duplexer network 170 to the service antennas 180 and then transmitted via the mobile station downlink to the plurality of mobile stations 40.

The down converter 111 is known in the art and has a first band pass filter 112 which is connected to a first low noise amplifier 113. The output of the first low noise amplifier 113 is connected to a first image reject filter 114. The output of the first image reject filter 114 is connected to a first mixer 116 to down convert the incoming telecommunications signals 20 to the intermediate frequency. The down converted signals are filtered in a first filter 118 before they are passed to the IF beamforming processor network 210.

The up converter 120 receives the phase shifted down converted telecommunications signals 204 from the IF beamforming processor network 210 and filters these in a second filter 121. The filtered signals are up converted by a second mixer 122 to the transmission frequency and the up converted signals are filtered in a third filter 123 before being passed to a power amplifier 124. The amplified signals are filtered by a second band pass filter 126 before being passed to a multiplexer network 127 and then to the second duplexer network 170 for transmission on the service antenna 180.

The signals for the first mixer 116 and the second mixer 122 are provided from a reference oscillator 140 connected to a frequency synthesizer 142 to generate the local oscillator signals LO1 and LO2. A first splitter network 144 passes the first local oscillator signal LO1 to the down converters 111 and a second splitter network 146 passes the local oscillator signal LO2 to the up converters 120.

The receiver network 150 is shown in the lower section of FIG. 2. It is basically a “mirror image” of the transmission network in the upper section of FIG. 2. The telecommunications signals are received from the service antennas 180 through the second duplexer network 170 and passed to a down converter 151. The down converter 151 comprises a third band pass filter 152 connected to a second low noise amplifier 154 and then to a second image reject filter 155. The telecommunications signals are then down converted using the third mixer 156 before being passed to a fourth filter 158 and thence to the IF beamforming processing network 210.

The output of the IF beamforming processing network 210 is passed to an up converter 160. The up converter 160 comprises a fifth filter 162 connected to a fourth mixer 164 for up converting the phase shifted down converted telecommunication signals 204 to the transmission frequency. The output of the fourth mixer 164 is passed to a sixth filter 165 and then to a second power amplifier 166 and to a fourth band pass filter 168. The output of the fourth band pass filter 168 is passed to a second output multiplexer network 169 and thence to the first duplexer network 107 for transmission on the donor antenna 105.

The third mixer 156 is provided with the second local oscillator signal LO2 from the reference oscillator 140 and the fourth mixer 164 is provided with the first local oscillator signal LO1 from the reference oscillator 140.

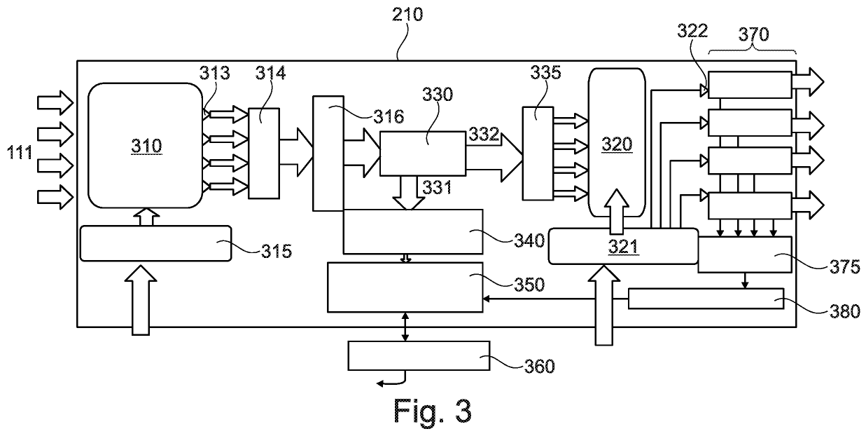

FIG. 3 shows a first example of the IF beam forming processor network 210. In this first example of the IF beam forming processor network 210, a first phase shifter 310 receives the down converted telecommunications signals 202 from the down converter 111 as shown by the arrows. The first phase shifter network 310 weights individual components of the down converted telecommunications signals 202 using weighting coefficients. The weighting coefficients used to weight the individual components are passed through from an electromechanical uplink controller 315 (from the donor antenna). These weighting coefficients are used to beamform the transmitted down converted telecommunications signals 202. This is done to direct the base station signal beam 22 in FIG. 1. The individual components of the phase shifted down converted telecommunications signals 204 are subsequently amplified by a plurality of first variable gain amplifiers 313. The gain factors for the plurality of first variable gain amplifiers 313 can also be set through the uplink controller 315. These gain factors will vary the amplitude of the beamforming coefficients.

The phase shifted and amplified individual components are passed to a combiner 314 where the outputs are combined to form the phase shifted down converted telecommunications signal 204 and then passed to a first coupler 330, through an optional low noise amplifier 316. The combiner 314 is, in one aspect of the invention, a Wilkinson combiner, which provides good isolation between the inputs. A first output 331 of the first coupler 330 couples a small proportion (for example 5-20%) of the power of the down converted phase shifted telecommunications signals 204 and detects the amount of power on the down converted phase shifted telecommunications signals 204 in a first power detector 340. The first power detector 340 is connected to a mobile device including a processor 350 which is able measure the amount of power on the beamformed signals. The extracted value of the amount of power will be used to optimize the signal to noise ratio on the transmitted telecommunications signals, as will be described later.

The processor 350 of a mobile device will send instructions back to the first phase shifter network 310 through the uplink controller 315 to adapt the values of the weighting coefficients used in the first phase shifter network 310. In the example shown FIG. 3, the extracted values of the power are transferred to an external antenna 360 which sends the extracted values to a network operator or controller (not shown). The network operator/controller sends adjustment values for the weighting coefficients back to the first phase shifter network 310 through the uplink controller 315. The purpose of the adjustment values is to shift the direction of the base station signal beam 22 and the power of the (adjusted or shifted) beam formed signal is measured again to see whether the power has increased or decreased. The adjustment of the weighting coefficients can be repeatedly carried out until a maximum value of power is reached. This will happen when the main lobe of the base station beam 20 corresponds to the direction of the base station mobile beam 22. In other words, there is a feedback loop to optimise the power received by the repeater 10 from the base station 30 and thus optimise the signal to noise ratio. It will be appreciated that the repeater 10 could be connected through a connector to a public computer network, such as the Internet, so that the values of the power and the weighting coefficients are sent through the public computer network to and from the network controller or operator.

A second output 332 of the first coupler 330 is connected to a splitter 335. The splitter 335 is, in one aspect of the design, a Wilkinson splitter providing good isolation between the inputs of the splitter 335 and splits the telecommunication signals. The splitter 335 transfers the individual components of the down converted phase shifted telecommunications signals 204 to a second phase shifter network 320 which receives control signals from a network operator/controller through a downlink electromechanical controller 321. The output signals of the second phase shifter network 320 are passed through second variable gain amplifiers 322 and then forwarded to the up converter 120 in FIG. 2. The outputs of the second phase shifter network 320 are coupled by a plurality of second couplers 370 where the power of the up converted telecommunications signals 206 is measured. The results of this power measurement are added together in a coupler 375 and passed to a second power detector 380. The value of the second power detector 380 is passed to the processor 350 for transmission to the network controller. The network controller can then change the value of the weighting coefficients in the second phase shifter network to optimise the signal to noise ratios of the up converted telecommunications signals 206 transmitted to the mobile stations 40 on the signal beam 24, in a similar many to that explained above.

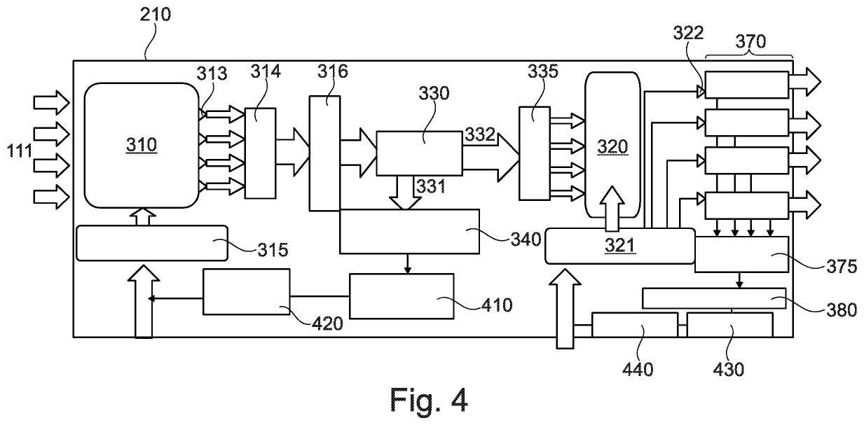

A second example of the IF beam forming processor network is shown in FIG. 4. In this example, similar elements in FIG. 4 and in other figures will have similar reference numerals as those shown in FIG. 3 except where the elements are different. The IF beam forming processor network 210 of FIG. 4 has the power detector 340 connected to the coupler 330 also connected to a first digitizer 410. The first digitizer 410 converts the value of the power and passes the values through a third coupler 420 internally connected to the uplink 315 and thence to the first phase shifter network 310. In other words, the detection of the power on the output signals of the first phase shifter network 310 is not sent to a network controller through an external antenna 360, as known from the example of FIG. 3, but is passed internally to the first phase shifter network 310. The adaptation based on the power of the weighting coefficients is carried out inside the repeater 10. This could be done, for example, by having a look up table connected to the uplink controller 315 or the first phase shifter network 315 to adapt the weighting coefficients as required or could include more complex processing equipment.

Three types of power detector 340 can be used, but this is not limiting of the invention. In a first aspect, the power detector 340 is an envelope detector where the output of the power detector 340 is proportional to the RF envelope amplitude. In a second aspect, a log detector is used as the power detector 340 and the output is proportional to RF envelope amplitude in dB. IN a third aspect of the invention, the power detector 340 is RMS (root mean square) to DC detector where the output of the power detector is proportional to RMS of RF signal power in dB (E_{RMS}=square root of the Average(Voltage²).

It will be appreciated that since only the power in the beam is detected, and not the information bandwidth, then requirements for the digitizer bandwidth for the power detector are substantially relaxed. This leads to a lower cost digitizer and a low cost repeater for Gbps transmission.

Similarly, the output of the power detector 380 is connected to a second digitizer 430 and then coupled into the downlink controller 321.

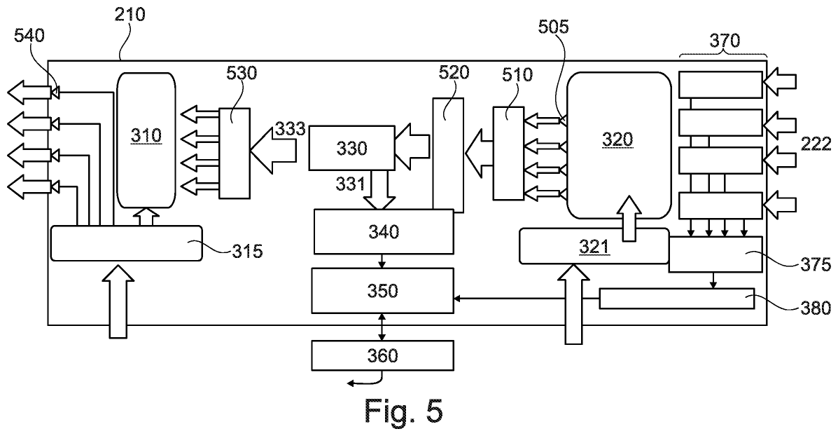

The repeater 10 can also act in the other direction. In the example shown in FIG. 5 the telecommunications signals are incoming from the plurality of mobile stations 40 through the signal beam 24 and are received by an antenna. The example of FIG. 5 shows the reverse direction, but the elements used in the IF beam forming processor network 210a are identical to those shown in FIG. 3 and their functions are essentially the same. In this case, however, the second phase shifter network 320? receives from the down converter 151 the down converted telecommunication signals 222a and phase shifts the down converted telecommunications signals 222. The phase shifted down converted telecommunications signals 224 are passed to third variable gain amplifiers 505 and thence to a third combiner 510. The combined telecommunications signals are optionally passed to a low noise amplifier 520 before being passed to the first coupler 330 where their power is detected in the power detector 340. The third output 333 of the first coupler 330 is passed to a fourth combiner 530 and thence to the first phase shifter network 310 and fourth variable gain amplifiers 540 before being up converted and transmitted to the base stations 30, as discussed above.

The weighting coefficients for the second phase shifter network 320 are received over the uplink controller 321 and the weighting coefficients for the first phase shifter network 310 are received over the downlink controller 315. The downlink controller 315 and the uplink controller 321 receive their control signals for an external network controller which receives information transmitted over the external antenna 360.

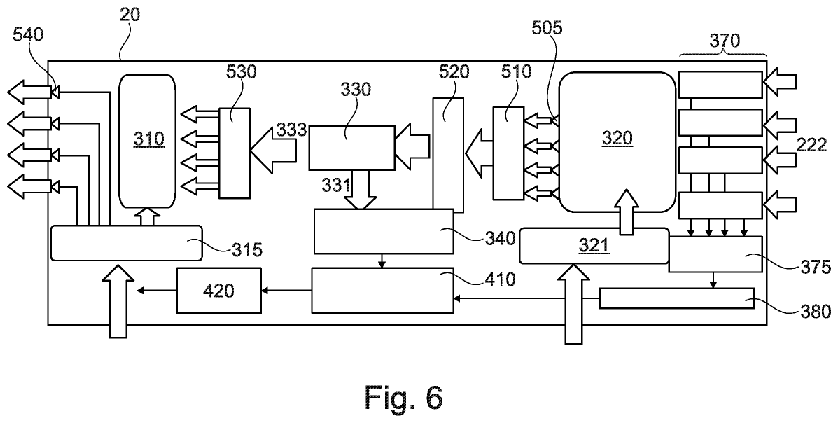

FIG. 6 shows a further aspect of the IF beamforming processor network 210 in which the down converted telecommunications signals 222 are received and passed through the IF beamforming processor network 210. In this case, in a manner like FIG. 4, information about the weighting coefficients is generated internally.

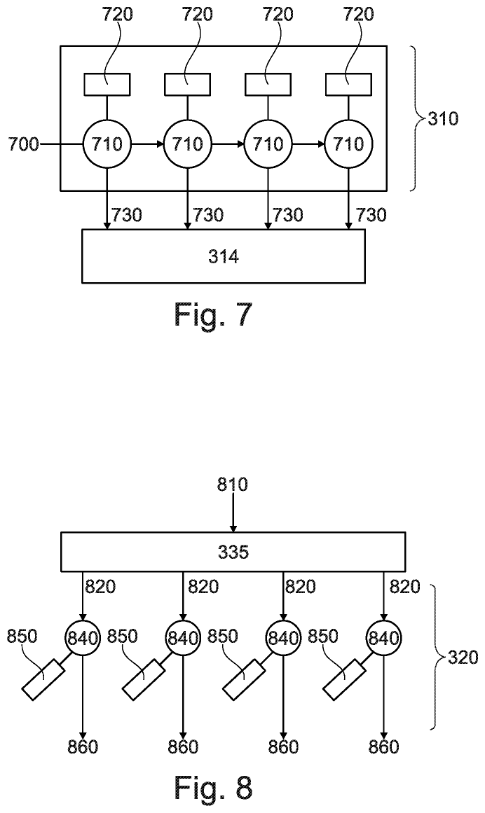

FIG. 7 shows an example of a first phase shifter network 310 which can be connected to the down converter 111. The first phase shifter 310 is connected, in the example of FIG. 7 to input 700 and has four phase shifters 710. The number of phase shifters 710 in not limiting of the invention. In this example of FIG. 7, the phase shifters 710 are rotary phase shifters with a terminated load 720 and an output 730. The four outputs 730 from the four phase shifters 710 are connected to the combiner 314.

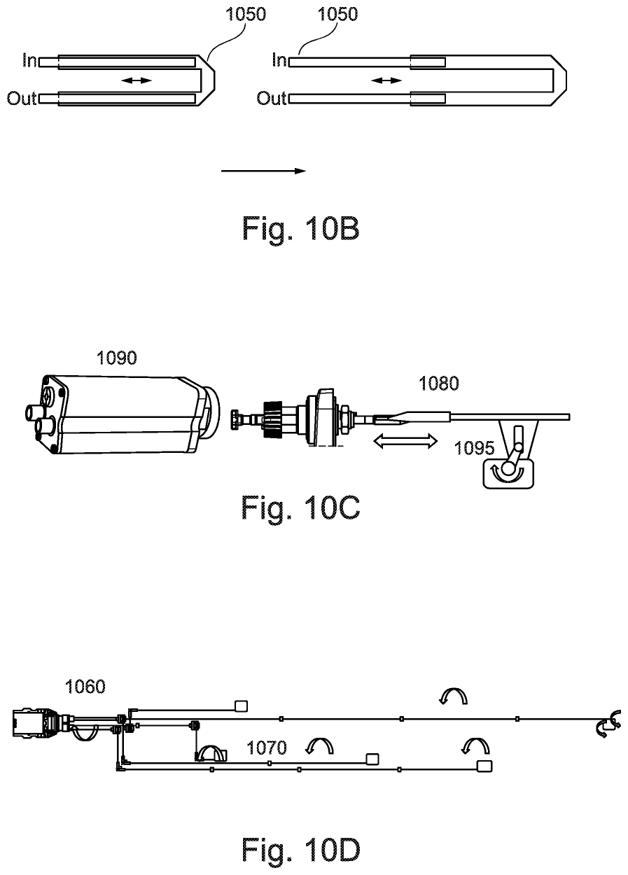

In one non-limiting embodiment, the phase shifters 710 are formed of an electromechanical motorised remote electrical tilt (RET) system 1060 having multiple shafts 1070, as shown in FIG. 10D. The shafts 1070 drive one or more of the phase shifters 710.

In another non-limiting embodiment, each phase shifters 710 are connected to a remote-control unit (RCU) 1080 with a linear motion shaft 1090, as shown in FIG. 10C. Multiple RCUs can be connected in daisy chain to drive phase shifter 710. This linear motion shaft 1090 may have a mechanical coupling mechanism 1095 to rotate each phase shifter.

In a further non-limiting embodiment. The phase shifter 710 are linear phase shifters, MEMS devices or trombone phase shifters 1050 (see FIG. 10B which shows movement).

FIG. 8 shows an example of the second phase shifter network 320. The telecommunications signals 810 are passed to the splitter 335 to produce individual components 820 of the telecommunications signals. The individual components 820 are passed to individual phase shifters 840 and phase shifted to produce beam formed output signals 860. The phase shifters 840 have a terminated load 850. As noted above, in one non-limiting embodiment, the phase shifters 840 are formed of a motorised remote electrical tilt (RET) system having multiple shafts. Each of the shafts drives one of the phase shifters 840. In another non-limiting embodiment, the phase shifters 840 are in a remote-control unit (RCU). In a further non-limiting embodiment. the phase shifter 840 are linear phase shifters, MEMS devices or a trombone phase shifter.

It will be appreciated that the first and second phase shifter networks 310 and 320 shown in FIGS. 7 and 8 can be adapted to relay telecommunications signals from the mobile stations 40 to the base station 30.

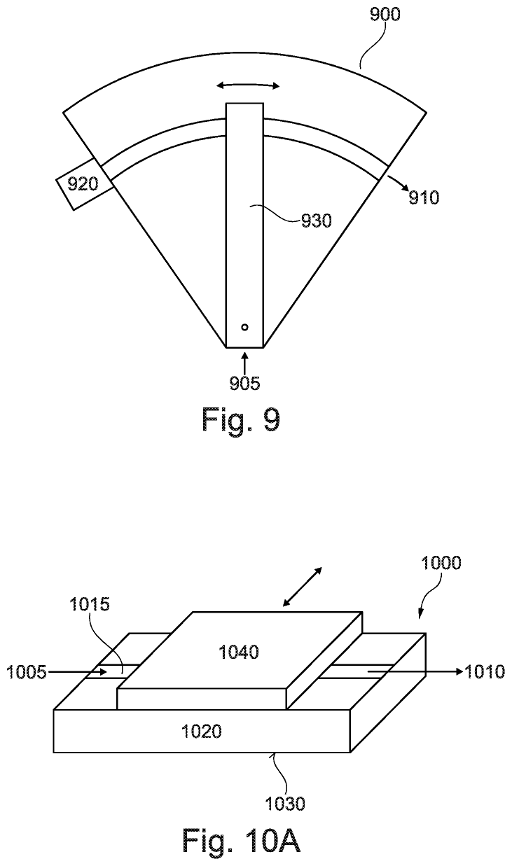

FIG. 9 shows an example of phase shifters 900 which can be used in the first phase shift network 310 and second phase shift network 320. The illustrated phase shifter 900 is a rotary phase shifter in which an input signal 905 is input and a phase shifted output signal 910 is produced. An arm 930 can be moved in a radial direction to change the length of the path traveled by the input signal 905 and thus change the phase of the output signal 910. The path is terminated on one end by a load 920. The phase shifter 900 is produced on a printed circuit board to give a cost-effective solution. An alternative implementation in metal conductors can be used as well.

FIG. 10 shows an example of a planar phase shifter 1000 which can be used in the first phase shift network 310 and second phase shift network 320. The input signal 1005 is phase shifted to produce an output signal 1010. The planar phase shifter 1000 has a stripline 1015 on the surface of substrate 1020 with a ground plane 1030 on the rear side (often referred as microstrip). A dielectric layer 1040 is moved transversely as shown by the arrow to change the velocity of the input signals 1005 in the stripline 1015 and thus change the phase of the output signal 1010. A trombone phase shifter can also be produced by this design.

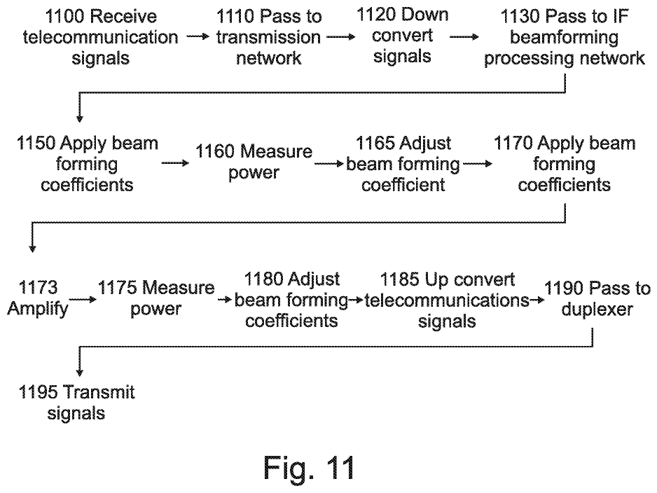

FIG. 11 shows an example of a method of operation of this repeater 10. In a first step 1100, the telecommunications signals on the base station signal beam 24 are received by the donor antenna 105 (seen in FIG. 3) and passed in step 1110 through the first duplexer network 107 to the transmission network 110. The incoming telecommunications signals are down converted in step 1120 in the down converter 111 to the intermediate frequency set by the first local oscillator frequency LO1. The down converted telecommunications signals 202 are passed to the IF beamforming processing network 210 in step 1130.

The first phase shifter network 310 has weighting coefficients and applies the weighting coefficient in step 1150 to the down converted telecommunications signals 202 to produce the phase shifted down converted telecommunications signals 204. The power of the output of the first phase shifter network 310, i.e. of the phase shifted down converted telecommunications signals 204, is measured in the first power detector 340 in step 1160. As noted above, there are several methods used by the first power detector 340 to detect the power, for example envelope detector, logarithm detector, RMS to DC detector, but these are not limiting of the invention. The information gained by the first power detector 340 can then be sent in step 1165 to the network operator to allow the network operator to adjust the weighting coefficients to optimise the signal-to-noise ratio (as discussed in connection with FIG. 3) or be processed internally to optimise the signal to noise ratio (as discussed in connection with FIG. 4).

The phase shifted down converted telecommunications signals 204 are further phase shifted in step 1170 by applying further weighting coefficients in the second phase shifter network 320 and in step 1173 amplified by the second variable gain amplifiers 322 to optimise transmission to the mobile stations 40. The power in the further phase shifted telecommunications signals is measured in step 1175 and in step 1180 the weighting coefficients in the second phase shifter network 320 are adjusted to maximise the signal-to-noise ratio. In step 1185, the signals are up converted in the up converter 120 before being passed in step 1190 through the second duplexer network 170 for transmission in step 1195 through the service antennas 180 to the mobile stations 40.

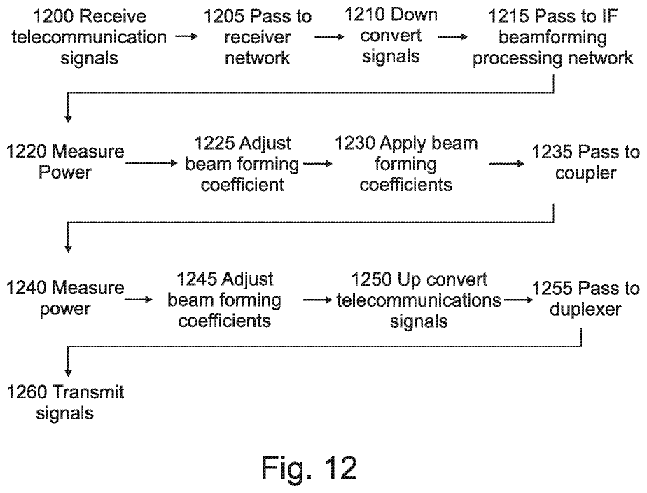

Similarly, FIG. 12 shows the situation in which telecommunications signals are received from the mobile stations 40 on the signal beam 24 in step 1200 by the service antennas 180 (in uplink mode from the mobile stations 24) and passed in step 805 through the second duplexer network 170 to the receiver network 150. The signals are down converted in step 1210 in the down converter 151 to the intermediate frequency and passed in step 1215 to the IF beamforming processing network 210. The power of the down converted telecommunications signals 222 is measured in step 1220 and in step 1225 weighting coefficients are adjusted in the second phase shifter network 320. The weighting coefficients are applied to phase shift the down converted telecommunications signals 222 in step 1230.

The output of the second phase shifter network 320 is passed in step 1235 to the first coupler 330 and the first power detector 340 measures the power in step 840 and passes the measured values of the power in step 1245 to enable the weighting coefficients in the first phase shifter network 310 to be controlled to maximise the signal to noise ratio on the transmitted telecommunications signals to the base station 30.

The down converted phase shifted telecommunications signals 202 are up converted in step 1250 and passed in step 1255 to first duplexer network 107 and transmitted in step 1260 to the base station 30 through the donor antenna 105.

In one aspect of the repeater, the weighting coefficients optimised in the beamforming network in FIG. 11 from the donor antenna 105 to the service antenna in FIG. 3 can also be used in FIG. 12 for the reverse paths.

### REFERENCE NUMERALS

10 Repeater
20 Signals
22 Base station signal beam
24 Signal beam
30 Base station
40 Mobile station
50 Obstruction
105 Donor antenna
107 First duplexer network
110 Transmission network
111 Down converter
112 First band pass filter
113 First low noise amplifier
114 First image reject filter
116 First oscillator
118 First filter
120 Up converter
121 Second filter
122 Second oscillator
123 Third filter
124 Power amplifier
126 Second band pass filter
127 Multiplexer network
140 Reference oscillator
142 Frequency synthesizer
144 First splitter network
146 Second splitter network
150 Receiver network
151 Down converter
152 Third band pass filter
154 Second low noise amplifier
155 Second image reject filter
156 Third oscillator
158 Fourth filter
160 Up converter
162 Fifth filter
164 Fourth oscillator
165 Sixth filter
166 Second power amplifier
168 Fourth band pass filter
169 Second output multiplexer network
170 Second duplexer network
180 Service antennas
202 Down converted telecommunications signals
204 Phase shifted down converted telecommunications signals
206 Up converted telecommunications signals
210 IF beamforming processing network
222 Down converted telecommunications signals
224 Phase shifted down converted telecommunications signals
226 Up converted telecommunications signals
310 First phase shifter network
313 First variable gain amplifiers
314 Combiner
315 Uplink controller
316 Low noise amplifier
320 Second phase shifter network
321 Downlink controller
322 Second variable gain amplifier
330 First coupler
331 First output
332 Second output
333 Third output
335 Splitter
340 First power detector
350 Processor
357 Adder
360 External antenna
370 Second coupler
375 Coupler
380 Second power detector
410 First digitizer
420 Third coupler
430 Second digitizer
440 Fourth coupler
505 Third variable gain amplifiers
510 Third combiner
520 Low noise amplifier
530 Fourth combiner
540 Fourth variable gain amplifiers
700 Inputs
710 Phase shifters
720 Terminated load
810 Telecommunication signals
820 Individual components
840 Phase shifters
850 Terminated load
860 Output signals
900 Rotary phase shifter
905 Input signal
910 Output signal
920 Load
930 Arm
1000 Phase shifter
1005 Input signal
1010 Output signal
1015 Stripline
1020 Substrate
1030 Ground plane
1040 Dielectric layer
1050 Trombone phase shifter
1060 Remote electrical tilt system
1070 Linear motion shafts
1080 Remote control unit
1090 Linear motion shaft
1095 Mechanical coupling mechanism

1. A repeater (10) for relaying telecommunication signals between a base station and a plurality of mobile users, the repeater comprising:
a downconverter for converting the telecommunications signals to down converted telecommunications signals at an intermediate frequency (IF) from a transmission frequency;
an up converter, converting the down converted telecommunication signals from an intermediate frequency to the transmission frequency; and
an IF beamforming processor network arranged between the downconverter and the up converter, wherein the IF beamforming processor network (210) comprises:
a first phase shifter network for phase shifting the down converted telecommunications signals to form the phase shifted down converted telecommunications signals;
a second phase shifter network for further phase shifting the phase shifted down converted telecommunications signals; and
a first coupler arranged between the first phase shifter network and the second phase shifter network, the first coupler being adapted for coupling a portion of the phase shifted down converted telecommunications signals and providing control signals to the first phase shifter network based on the coupled portion.

2. The repeater of claim 1, wherein a first power detector is connected to the first coupler for detecting the power of the phase shifted down converted telecommunication signals.

3. The repeater of claim 2, wherein the first power detector is one of an envelope detector, a log detector or a RMS to DC detector.

4. The repeater of claim 1, further comprising one of an external antenna or a network interface to a public computer network, the external antenna or the network interface being adapted for sending data about the phase shifted down converted telecommunications signals to an external network controller.

5. The repeater of claim 1, wherein the first phase shifter network has a first interface for accepting first control signals from the external network controller.

6. The repeater of claim 1, wherein the second phase shifter network has a second interface for accepting second control signals from the external network controller.

7. The repeater of claim 1, further comprising second couplers connected to outputs of the second phase shifter network.

8. The repeater of claim 7, further comprising a combiner for combining outputs of the second couplers.

9. The repeater of claim 7, further comprising a second power detector (380) for passing values of the power from the combiner to the processor.

10. The repeater of claim 1, wherein at least one of the first phase shifter network or the second phase shifter network are mechanically controlled phase shifters.

11. The repeater of claim 10, wherein the mechanically controlled phase shifters are formed from one or more electromechanical motorised systems with one or more shafts.

12. The repeater of claim 11, wherein the one of more electromechanical motorised systems comprise shafts and mechanical coupling mechanisms for providing at least one of linear or rotating motion to the mechanically controlled phase shifters to cause a change in the phase of the telecommunications signals.

13. The repeater of claim 1, wherein a signal beam of telecommunications signal between the repeater and the plurality of mobile users is in use a broad beam and adaptive.

14. The repeater of claim 1, further comprising a plurality of variable gain amplifiers for changing amplitude of components of the telecommunications signals.

15. A method for relaying telecommunications signals comprising:
down converting the telecommunication signals from a radio frequency to an intermediate frequency;
phase shifting (1150; 1230) the down converted telecommunications signals; measuring power (1160; 1220) of the phase shifted down converted telecommunications signals;
adjusting weighting coefficients dependent on the measured power: up converting (1185; 1250) the phase shifted down converted telecommunications signals: and
relaying the up converted telecommunications signals.

16. The method of claim 15 wherein the measuring of the power of the down converted telecommunication signals comprises measuring envelope of the beam formed telecommunications signals.

17. The method of claim 15, further comprising calculating adjusted ones of the weighting coefficients in a network controller.

18. The method of claim 15, further comprising looking up values for adjusted ones of the weighting coefficients in a look-up table.
